(19) United States
(12) Patent Application Publication
(10) Pub. No.: US 2010/0172064 A1
(43) Pub. Date: Jul. 8, 2010

(54) ELECTRIC APPARATUS FOR ELECTRIC POWER

(75) Inventor: Eiichi Takahashi, Shizuoka (JP)

Correspondence Address: FOLEY AND LARDNER LLP;SUITE 500, 3000 K STREET NW, WASHINGTON, DC, 20007, US

(73) Assignee: Meidensha Corporation

(21) Appl. No.: 12/663,935

(22) PCT Filed: Jun. 20, 2008
(86) PCT No.: PCT/JP2008/061341

§ 371 Date: Dec. 10, 2009

(30) Foreign Application Priority Data
Jul. 6, 2007 (JP) 2007-178276

(51) Int. Cl. H01G 5/04; H01G 2/10; H03K 17/975

(52) U.S. Cl. 361/296; 361/271; 200/600

(57) ABSTRACT

A shape of longitudinal section of a side wall of an insulation tube is formed into an arch. With this shape, as compared with a mere cylindrical insulation member, it is possible to elongate a creepage distance without extending a length in an axial direction of the insulation tube (a spatial distance between both conductive members) and to improve the insulation withstanding voltage characteristic against the shunt current. In addition, a surface area on an arch surface becomes large, thereby facilitating heat absorption on an arch surface on an inner peripheral surface side of the side wall and facilitating heat radiation on an arch surface on an outer peripheral surface side of the side wall.

### TECHNICAL FIELD

The present invention relates to a power electric apparatus, and can be applied to, for example, a variety of power capacitors (a variable vacuum capacitor, a fixed vacuum capacitor, a solid-state capacitor, an oil-filled capacitor, a ceramic capacitor, an oil capacitor etc.), a power switch (a vacuum valve, an oil switch etc.) and others.

### BACKGROUND ART

The power electric apparatus such as the power capacitor and the power switch has been applied to various facilities, and has been applied also to various high-frequency apparatuses and large power apparatuses etc. in recent years. For instance, in the case of the vacuum capacitor, it is applied to a high-frequency power supply for semiconductor facilities and also is used for impedance adjustment in the high-frequency apparatus of a large power oscillation circuit etc. In the case of the vacuum valve, it is used for shut-off/power-on (open/close) of the large power apparatus.

As a main structure of the power electric apparatus, the power electric apparatus having a casing, which is formed by closing both ends of a tubular insulation member (simply, a cylindrical insulation member) with conductive members of metallic material etc., has been known. For instance, in the case of the power capacitor, it is constructed so that capacitance is formed between both the conductive members in the casing. In the case of the power switch, it is constructed so that electrical switching can be possible by changing an electrical distance between the both conductive members. (For example, Patent Document 1)

FIG. 7 is a schematic view for explaining an example of a typical vacuum capacitor (a coaxial cylindrical electrode type). In FIG. 7, a reference sign 1 is a vacuum casing. The vacuum casing 1 is formed mainly from a tubular insulation member (e.g. a member made of ceramic material; hereinafter called an insulation tube) 2 and conductive members (e.g. members made of metal such as copper) 2a, 2b which are provided on one end side and the other end side of the insulation tube 2.

As can be seen from the drawing, for instance, the conductive members 2a, 2b could be formed from metal cylinders 3, 4 which are provided on the one end side and the other end side of the insulation tube 2 and flanges (flanges on a movable electrode side and a fixed electrode side; hereinafter called a movable side flange and a fixed side flange) 5, 6 which are provided to close the insulation tube 2 and the metal cylinders 3, 4. The movable side flange 5 and the fixed side flange 6 could be used as external terminals.

A reference sign 7 is a fixed electrode that is formed from a plurality of cylindrical electrode members whose inside diameters are different from each other. Each electrode member is provided concentrically on an inner side of the fixed side flange 6 (inside the vacuum casing 1) at a predetermined distance. A reference sign 8 is a movable electrode that is formed from a plurality of cylindrical electrode members whose inside diameters are different from each other, same as the fixed electrode 7. Each electrode member is provided inside the vacuum casing 1 so that the each electrode member can be inserted into and extracted from the fixed electrode 7 (the each electrode member is inserted into and extracted from a gap between the electrode members of the fixed electrode 7 then the electrode members of the both movable and fixed electrodes 8, 7 alternate with each other) with the each electrode member in a noncontact state with the fixed electrode 7.

A reference sign 9 is a movable conductor. The movable conductor 9 is formed from a movable side supporting plate 9a which can move in an axial direction of the vacuum casing 1 and supports the movable electrode 8 and a movable rod 9b which protrudes from a back surface (a surface on which the movable electrode 8 is not secured) of the movable side supporting plate 9a. The movable rod 9b is slidably supported by a bearing portion 10 which is provided at the movable side flange 5.

A reference sign 11 is soft metal bellows, as a part of current path of the vacuum capacitor. The bellows 11 are set so that a space (hereinafter called a vacuum chamber) enclosed by the fixed electrode 7, the movable electrode 8 and the bellows 11 inside the vacuum casing 1 is kept airtight (to produce vacuum) and also the movable electrode 8 and the movable conductor 9 can move in the axial direction of the vacuum casing 1. For example, as shown in the drawing, one side edge is connected with the movable conductor 9, and the other end side edge is connected with the bearing portion 10.

By moving the movable conductor 9 in the axial direction and inserting and extracting the movable electrode 8 into and from the fixed electrode 7 (inserting and extracting the movable electrode 8 into and from the fixed electrode 7 so that the respective electrode members of the both electrodes 7, 8 alternate with each other), an area between facing electrodes (an overlap area between the fixed electrode 7 and the movable electrode 8) changes. With this, when applying voltage of the opposite polarity to the both electrodes 7, 8 respectively, a value of capacitance appearing between the both electrodes 7, 8 is seamlessly changed, then the impedance adjustment is made.

Regarding high frequency current for the high-frequency apparatus of a case using such vacuum capacitor, the high frequency current flows from the movable side flange 5 to the fixed side flange 6 through the bellows 11 and the capacitance between the facing electrodes. Nowadays, a load used in the high-frequency apparatus becomes large, and the high frequency current increases with increase of the load. Thus an apparatus that is able to frequently adjust the flow of the large current is required.

With regard to the above-mentioned insulation tube, a structure that can obtain a desired insulation withstanding voltage characteristic is required. Therefore, for instance, by extending a length in the axial direction of the insulation tube (merely extending a spatial shortest distance (hereinafter called a spatial distance) between the both conductive members), or by thickening a thickness of a side wall, the insulation withstanding voltage characteristic could be improved.

However, in the above power capacitor and power switch, heat is generated by current energization during an operation, and this electrical heating becomes large with magnitude of scale of the apparatus and might increase to a considerable level. When a temperature in the insulation tube increases by the electrical heat generation, the insulation withstanding voltage characteristic of the insulation tube deteriorates. In particular, because an electric conductivity of the insulation tube is lower than that of the conductive member, for instance, as described above, in the case of the structure that is formed by merely extending the length in the axial direction of the insulation tube (merely extending the spatial distance between the both conductive members) or by merely thickening the thickness of the side wall, the temperature in the insulation tube rises easily.

On the other hand, when merely shortening the length in the axial direction of the insulation tube (merely shortening the spatial distance between the both conductive members), for instance, a shunt current increases, and the electrical heat generation may occur in the insulation tube. Further, although a way of thinning the thickness of the side wall could be considered, since a structure that is able to withstand various stresses (a high stress-resistant structure; e.g. a structure that is able to withstand the bending, the flexion and the cracking etc.) is required of the insulation tube, this way has limitations.

In view of the foregoing, the power electric apparatus such as the power capacitor and the power switch is required to enhance heat radiation efficiency with consideration given to the electrical heat generation during the operation and to improve the insulation withstanding voltage characteristic with consideration given to the shunt current etc.

Patent Document 1 : Japanese Patent Application Publication No. JP3264005

### DISCLOSURE OF THE INVENTION

According to one aspect of the present invention, a power electric apparatus of a power capacitor has a casing which is formed by closing both ends of a tubular insulation member (an insulation tube) with conductive members, and forms capacitance between the both conductive members in the casing, and a shape of longitudinal section of a side wall of the insulation member is arch shape.

According to another aspect of the present invention, the casing is a vacuum casing, a fixed electrode is installed at one of the conductive members in the vacuum casing, a movable electrode is installed at the other of the conductive members in the vacuum casing to form the capacitance between the fixed electrode and the movable electrode, and by moving the movable electrode and changing a position of the movable electrode with respect to the fixed electrode, the capacitance can be changed.

According to a further aspect of the invention, a power electric apparatus of a switch has a casing which is formed by closing both ends of a tubular insulation member with conductive members, and allows open/close between the both conductive members electrically by changing an electrical distance between the both conductive members in the casing, and a shape of longitudinal section of a side wall of the insulation member is arch shape.

According to a still further aspect of the invention, the casing is a vacuum casing, a fixed electrode is installed at one of the conductive members in the vacuum casing, a movable electrode is installed at the other of the conductive members in the vacuum casing, and by moving the movable electrode and changing a position of the movable electrode with respect to the fixed electrode, the open/close between the movable electrode and the fixed electrode can be electrically performed.

According to a still further aspect of the invention, an inside diameter and an outside diameter of the side wall of the tubular insulation member are set so that as a position of each diameter becomes closer to a middle from the both end sides in an axial direction of the insulation member, the diameter becomes greater, and also each shape of longitudinal section of an inner peripheral surface and an outer peripheral surface of the side wall is the arch shape.

According to a still further aspect of the invention, an inside diameter and an outside diameter of the side wall of the tubular insulation member are set so that as a position of each diameter becomes closer to a middle from the both end sides in an axial direction of the insulation member, the diameter becomes smaller, and also each shape of longitudinal section of an inner peripheral surface and an outer peripheral surface of the side wall is the arch shape.

According to a still further aspect of the invention, the insulation member is made of ceramic material.

In view of the foregoing, as compared with a mere cylindrical insulation tube, a creepage distance (a shortest distance along a surface of the insulation tube between the both conductive members) on an arch shaped surface (hereinafter called an arch surface) of the insulation tube becomes long, and also a surface area on the arch surface becomes large. That is, it is possible to elongate the creepage distance without extending a length in an axial direction of the insulation tube (a spatial distance between the both conductive members). In addition, the surface area on the arch surface becomes large, thereby facilitating heat radiation on an arch surface on an outer peripheral surface side of the side wall and facilitating heat absorption on an arch surface on an inner peripheral surface side of the side wall.

Further, as a structure having the vacuum casing, in the case where the inside diameter and the outside diameter of the insulation tube are set so that as the position of the diameter of the side wall becomes closer to the middle from the both end sides in the axial direction of the insulation member, the diameter becomes greater, and also each shape of longitudinal section of the inner peripheral surface and the outer peripheral surface of the side wall is the arch shape, stress-resistance against a stress in a direction from an outer peripheral side to an inner peripheral side of the insulation tube can be built up. For instance, when forming the vacuum casing, as compared with a mere cylindrical insulation tube, the stress-resistance against a stress that results from the vacuum in the vacuum casing is built up. That is, when the stress-resistance is high, even if the thickness of the side wall of the insulation tube is thinned, an adequate mechanical strength can be easily gained. And also, by thinning the thickness of the side wall, a heat conductivity of the insulation tube is increased.

Moreover, in the case where the inside diameter and the outside diameter of the insulation tube are set so that as the position of the diameter of the side wall becomes closer to the middle from the both end sides in the axial direction of the insulation member, the diameter becomes smaller, and also each shape of longitudinal section of the inner peripheral surface and the outer peripheral surface of the side wall is the arch shape, stress-resistance against a stress in a direction from the inner peripheral side to the outer peripheral side of the insulation tube can be built up.

### BRIEF DESCRIPTION OF THE DRAWINGS

FIG. 1 is a schematic view for explaining an example of a power electric apparatus (a variable vacuum capacitor) according to the present embodiment.

FIG. 2 is a sectional view of an insulation tube used in an embodiment 1.

FIG. 3 is a sectional view of a typically used insulation tube.

FIG. 4 is a sectional view of a power electric apparatus (a fixed vacuum capacitor) according to an embodiment 2.

FIG. 5 a sectional view of a power electric apparatus (a vacuum valve) according to an embodiment 3.

FIG. 6a sectional view showing other embodiment of the insulation tube according to embodiments 1˜3.

FIG. 7 is a schematic view for explaining a typical power electric apparatus (a variable vacuum capacitor).

### DESCRIPTION OF THE PREFERRED EMBODIMENTS

The present embodiment is a power electric apparatus such as a power capacitor and a power switch, which has a casing that is formed by closing both ends of an insulation tube with conductive members, and a shape of longitudinal section of a side wall of the insulation tube is formed into an arch.

For example, in a conventional art, in order to improve the insulation withstanding voltage characteristic against the shunt current in the power electric apparatus having a mere cylindrical insulation tube, a way of merely extending the length in the axial direction of the insulation tube (the spatial distance) or merely thickening the thickness of the side wall has been employed. However, according to the present embodiment, since a creepage distance becomes longer, it is possible to improve the insulation withstanding voltage characteristic without setting the spatial distance and the thickness of the side wall to be large.

### Embodiment 1

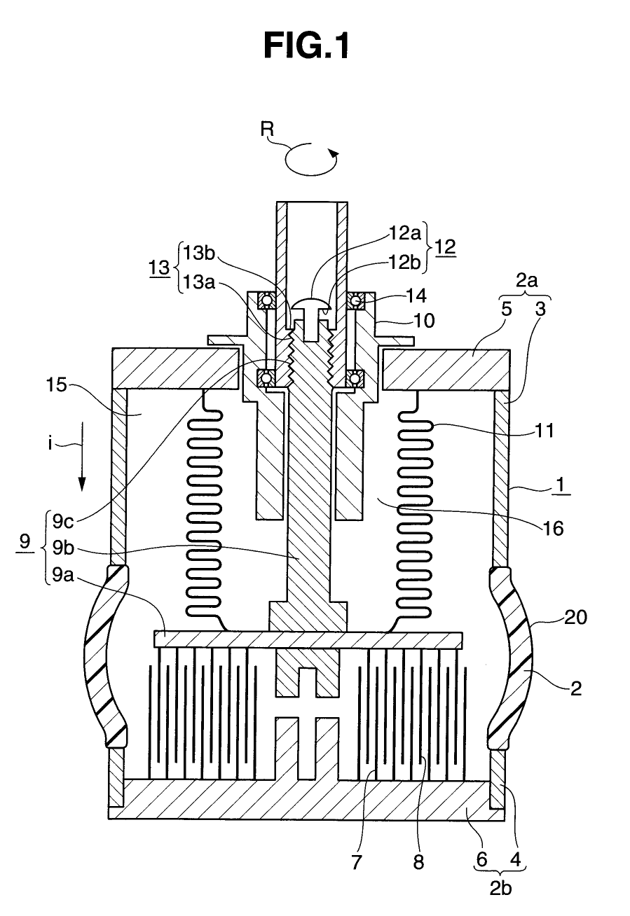

FIG. 1 is a schematic view for explaining an example of a vacuum capacitor (a variable vacuum capacitor) of a power electric apparatus, of the present embodiment. The variable vacuum capacitor is formed mainly from a vacuum casing 1 that has an insulation tube (an insulation member; e.g. a tubular insulation member made of insulation material such as ceramic material) 2 and conductive members (e.g. members made of metal such as copper) 2a, 2b which are provided on one end side and the other end side of the insulation tube 2, same as FIG. 7. The conductive members 2a, 2b are respectively formed from metal cylinders 3, 4, which are provided on the one end side and the other end side of the insulation tube 2, and a movable side flange 5 and a fixed side flange 6, which are provided to close the insulation tube 2 and the metal cylinders 3, 4 and used also as external terminals.

In the vacuum casing 1, a fixed electrode 7 that is formed from a plurality of cylindrical electrode members whose inside diameters are different from each other, is provided on an inner side of the fixed side flange 6 (inside the vacuum casing 1). And, same as the fixed electrode 7, a movable electrode 8 that is formed from a plurality of cylindrical electrode members which are provided concentrically at a predetermined distance and whose inside diameters are different from each other, is provided. The movable electrode 8 is set so that the movable electrode 8 can be inserted into and extracted from the fixed electrode 7 (the each electrode member is inserted into and extracted from a gap between the electrode members of the fixed electrode 7 then the electrode members of the both movable and fixed electrodes 8, 7 alternate with each other) with the each electrode member in a noncontact state with the fixed electrode 7.

The movable electrode 8 is supported by a movable conductor 9 that is formed from a movable side supporting plate 9a which can move in an axial direction of the vacuum casing 1 and supports the movable electrode 8 and a movable rod 9b which protrudes from a back surface (a surface on which the movable electrode 8 is not secured) of the movable side supporting plate 9a to an outward direction of the vacuum casing 1 (in a direction of the movable side flange 5) . The movable rod 9b has a male screw part (which can be screwed into an after-mentioned insulation control member) 9c at one end side of the movable side flange 5. And the movable rod 9b is inserted into a bearing portion (in the drawing, a supporting member having a thrust bearing 14 to reduce a rotation torque outside the vacuum casing 1) 10 which is provided in the vacuum casing 1 (in the drawing, the bearing portion 10 is secured so that the bearing portion 10 penetrates the movable side flange 5).

In addition, a vacuum chamber 15 is defined on a movable electrode 8 side and a fixed electrode 7 side by bellows (in the drawing, bellows connected between the movable side flange 5 and the movable side supporting plate 9a (for instance, through vacuum high temperature brazing)) 11, and an atmospheric chamber 16 is defined on a movable conductor 9 side. As the bellows 11, material having durability (mechanical strength etc.) and conductivity is used. For instance, it is the one that is made of phosphor bronze or a copper-clad SUS member.

A reference sign 13 is a tubular member (hereinafter called the insulation control member) which moves the movable rod 9b in the axial direction of the vacuum casing 1 and adjusts capacitance of the vacuum capacitor. The insulation control member 13 is rotatably supported on one end side of the bearing portion 10 (in the drawing, on a thrust bearing 14 side). At a middle portion inside the insulation control member 13, a stepped part 13b is formed. And at one end side from the stepped part 13b, a small-diameter (smaller than the other end side) female screw part 13a is formed. The male screw part 9c of the movable rod 9b screws into the female screw part 13a. On the other end side, a drive source (e.g. a motor, not shown) of the vacuum capacitor is connected (for instance, via an insulation means).

By rotating the insulation control member 13 (for example, in a rotation direction of an arrow R in the drawing) by means of the drive source, the movable conductor 9 moves in the axial direction while rotating in accordance with a shape of the female screw part 13a, and an area between facing electrodes (an overlap area between the fixed electrode 7 and the movable electrode 8) changes. As can be seen in the drawing, since a body of the movable rod 9b is inserted into the bearing portion 10, wobble of the movable conductor 9 can be suppressed upon the movement of the movable conductor 9. Further, for instance, by attaching a stopper screw (a screw having a seat 12b whose inside diameter is greater than the female screw part 13) 12 to the movable conductor 9, a movable range of the movable conductor 9 can be limited (for instance, contact between the facing electrodes can be prevented).

With respect to the insulation tube 2 of the embodiment 1, an insulation tube whose side wall has an arch shape in longitudinal section is employed. More specifically, a diameter of an arch surface (in the embodiment 1, it is an outer peripheral surface, an inner peripheral surface) is set so that as a position of the diameter becomes closer to a middle from both end sides of the arch, the diameter becomes greater. By using the insulation tube having such shape, a creepage distance of the insulation tube becomes longer, as compared with a mere cylindrical insulation tube.

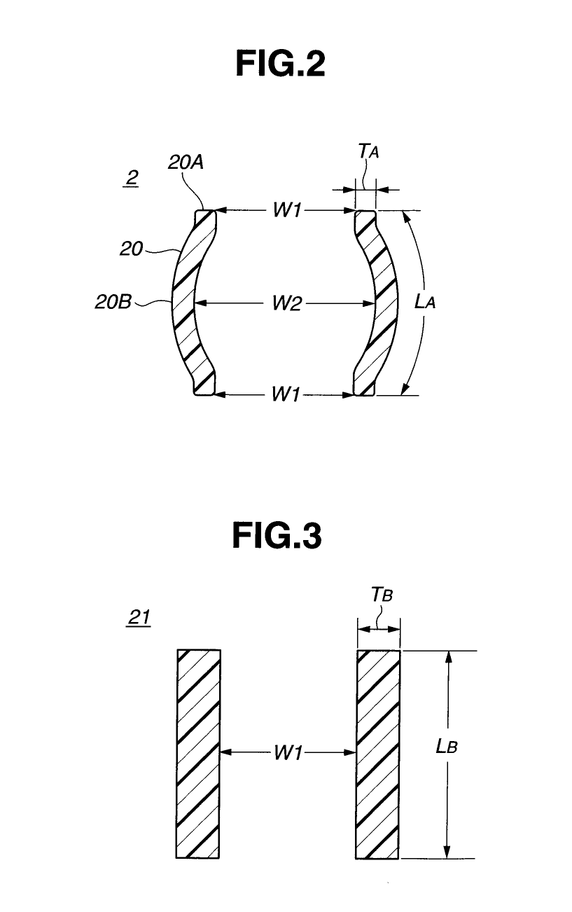

For example, as shown by a barrel-shaped insulation tube in FIG. 2, a curved portion 20 is formed so that as a position of a diameter of an insulation tube inner peripheral surface becomes closer to an insulation tube middle portion 20B from an insulation tube end portion 20A, the diameter of the insulation tube inner peripheral surface gradually becomes greater from W1 (an end portion inner peripheral surface diameter) to W2 (a middle portion inner peripheral surface diameter) and also so that a diameter of an insulation tube outer peripheral surface gradually becomes greater likewise. In this case having the structure of the embodiment 1, the structure can withstand a stress due to the vacuum in the vacuum casing 1 (the structure becomes a high stress-resistant structure; e.g. a structure that is able to withstand the bending, the flexion and the cracking etc.). And in accordance with degree of effect by the structure (e.g. in accordance with a difference between the middle portion inner peripheral surface diameter W2 and the end portion inner peripheral surface diameter W1), a thickness T_{A} of the side wall of the insulation tube 2 can be thinned and also a creepage distance L_{A} can be extended without loss of the mechanical strength of the insulation tube 2.

As a consequence, for instance, as compared with the case of FIG. 7, the creepage distance of the insulation tube 2 becomes long without extending the spatial distance, and the shunt current can be suppressed according to the length of the creepage distance, then the insulation withstanding voltage of the vacuum capacitor can be improved and a current capacity is increased. Further, since the thickness T_{A} of the side wall is thin and the arch surface of the inner peripheral surface is curved (the arch surface is curved in an outward direction of the vacuum casing), the volume of the vacuum casing 1 is increased, and heat radiation efficiency of the heat generation that may occur in the insulation tube 2 can be enhanced. Moreover, the side wall of the insulation tube is formed (in the embodiment 1, the inside diameter and the outside diameter of the insulation tube are set) so that as the position of each diameter becomes closer to the middle from the both end sides in the axial direction of the insulation member, the diameter becomes greater, and also the each shape of longitudinal section of the inner peripheral surface and the outer peripheral surface of the side wall is the arch shape. Therefore adequate stress-resistance can be obtained.

Here, a study of the heat generation in the insulation tube 2 will be carried out. For example, as shown in FIG. 3, when a thickness of a side wall of a conventional art insulation tube (hereinafter called a conventional insulation tube) 21, which is applied to the typical high-frequency apparatus etc., is T_{B}, if the thickness T_{B} is merely thinned, the conventional insulation tube 21 is prone to break. On the other hand, according to the structure of the insulation tube 2 of the present embodiment 1, in a case where the insulation tube 2 obtains the same stress-resistance as the conventional insulation tube 21, the thickness T_{A} of the insulation tube 2 can be reduced (thinned) by 30˜40 percent of T_{B}, and the creepage distance L_{A} can be increased (extended) by 10˜20 percent of L_{B}.

In other wards, according to the insulation tube 2 of the present embodiment 1, when each size of the conventional insulation tube 21 is 10, the thickness T_{A} of the insulation tube 2 can be reduced to 7˜6, and the creepage distance L_{A} can be increased to 11˜12.

With regard to capacitance C of the coaxial cylindrical electrode type, it can be calculated from a formula [C =2π×ε₀×εᵣ×(counter electrode distance)×Logₑ(b/a)] (here, ε₀ is the electric constant, εᵣ is the relative dielectric constant of material, a is a radius of an innermost peripheral side electrode, and b is a radius of an outermost peripheral side electrode). Thus, assuming that “ε₀×εᵣ” is 1 (ε₀×εᵣ=1), the following expression can be applied to calculation of the capacitance C of the insulation tube 2 or the conventional insulation tube 21 by the above index values.

C=ε₀·ε₁T/L

Here, in the above expression, ε₀ is the electric constant, ε₁ is the relative dielectric constant of the insulation tube, T (T_{A} or T_{B}) is a thickness of the insulation tube, and L (L_{A} or L_{B}) is a creepage distance of the insulation tube. In the above expression, when “ε₀·ε₁” is 1 (ε₀·ε₁=1) and each index value of the conventional insulation tube 21 is T_{B} =10, L_{B} =10, the capacitance C of the conventional insulation tube 21 is 1 (F) . On the other hand, when each index value of the insulation tube 2 of the present embodiment is T_{A}=7, L_{A}=12 in the above expression, the capacitance C of the insulation tube 2 is 0.58 (F).

Next, in a case where a calculation of a shunt current I that passes through the insulation tube 2 or the conventional insulation tube 21 is made, when capacitance of the insulation tube is C, capacitance of the electrode is C1 and current supplied to the electrode is I1, the following expression can be applied to the calculation of the shunt current I.

I=(all current)×((insulation tube capacitance C)/((insulation tube capacitance C)+(electrode capacitance C1)))=(I+I1)×C/(C+C1) Here, when C1 is 1 (C1=1) and I1 is 1 (I1=1), the shunt current I passing through the conventional insulation tube 21 is 1 (A), while the shunt current I of the insulation tube 2 is 0.58 (A).

In the vacuum capacitor of the present embodiment, even though the movable electrode 8 moves toward or apart from the fixed electrode 7 in the noncontact state, impulse caused by the movement of the movable electrode 8 becomes small. Then, even if the side wall thickness T_{A} of the insulation tube 2 is thin, the insulation tube 2 is resistant to break. Furthermore, since the movable conductor 9 moves smoothly in the bearing portion 10, the impulse becomes smaller, thus even if the side wall thickness T_{A} of the insulation tube 2 is thin, the insulation tube 2 is resistant to break.

### Embodiment 2

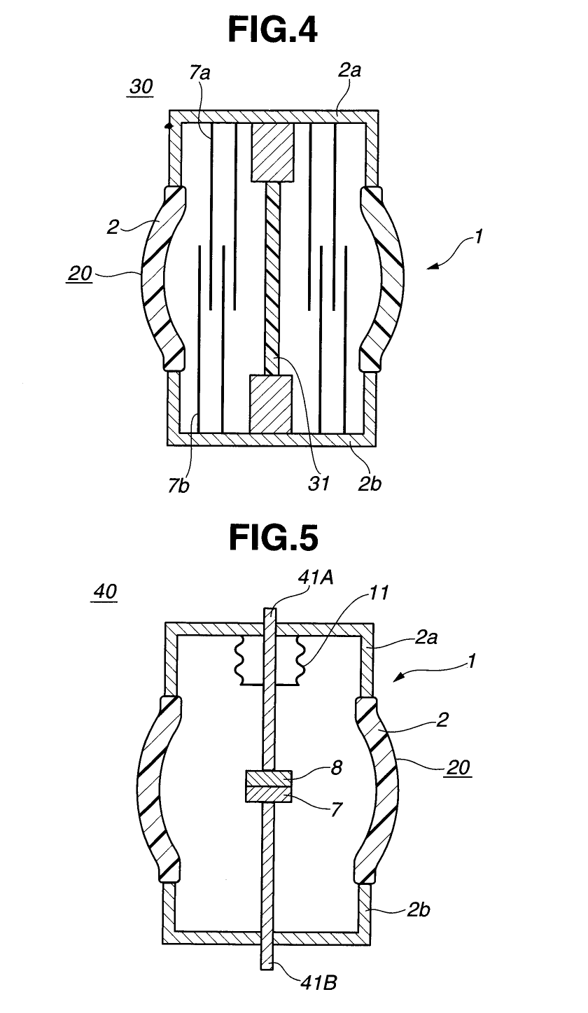

A reference sign 30 in FIG. 4 shows another example of the vacuum capacitor (a fixed vacuum capacitor) of the power electric apparatus according to the present embodiment. The fixed vacuum capacitor is formed mainly from a vacuum casing 1 that has an insulation tube (an insulation member; e.g. a tubular insulation member made of insulation material such as ceramic material) 2 and conductive members (e.g. members made of metal such as copper) 2a, 2b which are provided on one end side and the other end side of the insulation tube 2, same as the embodiment 1. In addition, same as the embodiment 1, the insulation tube 2 is formed (in the embodiment 2, an inside diameter and an outside diameter of the insulation tube 2 are set) so that as a position of a diameter of a side wall becomes closer to the middle from the both end sides in the axial direction of the insulation member, the diameter becomes greater. Further, each shape of longitudinal section of the inner peripheral surface and the outer peripheral surface of the side wall is an arch shape (in the drawing, the insulation tube is a barrel-shaped insulation tube).

In the present embodiment 2, fixed electrodes 7a, 7b (each electrode is an anode or a cathode) are provided inside the conductive members 2a, 2b (inside the vacuum casing 1). These fixed electrodes 7a, 7b are those that are formed from a plurality of cylindrical electrode members which are provided concentrically at a predetermined distance and whose inside diameters are different from each other. And the fixed electrodes 7a, 7b face each other so that the electrode members of the fixed electrodes 7a, 7b alternate with each other in the noncontact state and the capacitance is formed. In the drawing, a reference sign 31 is a center pin (a ceramic center pin etc.) for positioning of the fixed electrodes 7a, 7b. However, the present embodiment could be possible without the center pin 31.

Also in the case of the fixed vacuum capacitor shown in the present embodiment 2, the structure in which the side wall of the insulation tube has the arch shape in longitudinal section is employed. More specifically, the structure in which, the inside diameter and the outside diameter of the side wall are set so that as the position of each diameter becomes closer to the middle from the both end sides in the axial direction of the insulation member, the diameter becomes greater, and also the each shape of longitudinal section of the inner peripheral surface and the outer peripheral surface of the side wall is the arch shape, is employed. By using the insulation tube having such shape, the creepage distance of the insulation tube becomes longer, as compared with a mere cylindrical insulation tube.

For example, as shown by a barrel-shaped insulation tube 2 in FIG. 2, the curved portion 20 is formed so that as the position of the diameter of the insulation tube inner peripheral surface becomes closer to the insulation tube middle portion 20B from the insulation tube end portion 20A, the diameter of the insulation tube inner peripheral surface gradually becomes greater from W1 (the end portion inner peripheral surface diameter) to W2 (the middle portion inner peripheral surface diameter) and also so that the diameter of the insulation tube outer peripheral surface gradually becomes greater likewise. That is to say, with the structure of the present embodiment 2, the embodiment 2 can obtain the same function and effect as the embodiment 1.

### Embodiment 3

A reference sign 40 in FIG. 5 shows an example of a vacuum valve of the power electric apparatus according to the present embodiment. The vacuum valve is formed mainly from a vacuum casing 1 that has an insulation tube (an insulation member; e.g. a tubular insulation member made of insulation material such as ceramic material) 2 and conductive members (e.g. members made of metal such as copper) 2a, 2b which are provided on one end side and the other end side of the insulation tube 2, same as the embodiment 1. In addition, same as the embodiment 1, the insulation tube 2 is formed (in the embodiment 3, an inside diameter and an outside diameter of the insulation tube 2 are set) so that as a position of a diameter of a side wall becomes closer to the middle from the both end sides in the axial direction of the insulation member, the diameter becomes greater. Further, each shape of longitudinal section of the inner peripheral surface and the outer peripheral surface of the side wall is an arch shape (in the drawing, the insulation tube is a barrel-shaped insulation tube).

In the present embodiment 3, a pair of fixed electrode 7 and movable electrode 8 are installed inside the vacuum casing 1. Further, rods 41A, 41B are provided so that the rods 41A, 41B protrude out of the vacuum casing 1 from the respective back surfaces of the electrodes 7, 8 (in the drawing, the rods 41A, 41B protrude in the axial direction of the vacuum casing 1). Additionally, between the movable electrode side rod 41A and a movable side flange 5, bellows 11 by which an inside of the vacuum casing 1 is kept airtight (vacuum) and the movable electrode side rod 41A can move is provided. For instance, by moving the movable electrode side rod 41A (in the drawing, y moving the movable electrode side rod 41A in the axial direction of the vacuum casing 1), the fixed electrode 7 and the movable electrode 8 can be connected with and disconnected from each other. Thus, an operation of shut-off/power-on (open/close) of power by the vacuum valve can be carried out.

Also in the case of the vacuum valve shown in the present embodiment 3, the structure in which the side wall of the insulation tube has the arch shape in longitudinal section is employed. More specifically, the structure in which, the inside diameter and the outside diameter of the side wall are set so that as the position of each diameter becomes closer to the middle from the both end sides in the axial direction of the insulation member, the diameter becomes greater, and also the each shape of longitudinal section of the inner peripheral surface and the outer peripheral surface of the side wall is the arch shape, is employed. With this structure, the embodiment 3 can obtain the same function and effect as the embodiment 1. For example, as previously mentioned above, the electrical heat generation occurs upon the shut-off/power-on of power in the vacuum valve. However, with the structure shown in the present embodiment 3, a cooling effect increases with increase in the volume of the vacuum casing, and heat generated in the vacuum valve is efficiently radiated and the temperature can be decreased.

As is clear from the above-described embodiment 1-3, in the power electric apparatus such as the power capacitor and the power switch, having the casing which is formed by closing the both ends of the insulation tube with the conductive members, by employing the structure in which the side wall of the insulation tube has the arch shape in longitudinal section, it was found out that the creepage distance becomes long along the arch surface. And also, since a surface area on the arch surface becomes larger, it was found out that the heat radiation efficiency against the electrical heat generation during the operation of the power electric apparatus can be enhanced and the insulation withstanding voltage characteristic against the shunt current can be improved.

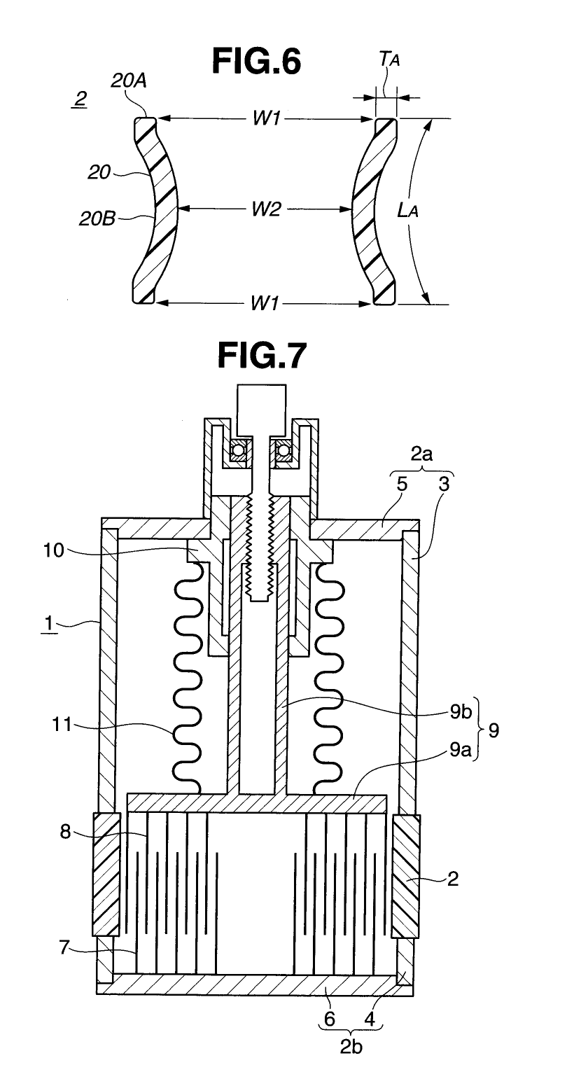

The embodiments 1-3 in which, the inside diameter and the outside diameter of the insulation tube are set so that as the position of the diameter of the side wall becomes closer to the middle from the both end sides in the axial direction of the insulation member, the diameter becomes greater, and also each shape of longitudinal section of the inner peripheral surface and the outer peripheral surface of the side wall is the arch shape, have been explained. However, as shown by an insulation tube in FIG. 6, even in the following structures: a structure in which the arch shape is formed so that as the position of the diameter of the arch surface becomes closer to the middle from the both end sides, the diameter becomes smaller, or a structure in which a vertex of the arch surface (position where the inside and outside diameters of the side wall are the largest or smallest) shifts from the middle to either one of the both end sides, or a structure in which an inside of the vacuum casing is not vacuum (e.g. an oil-filled capacitor, a solid-state capacitor, an oil capacitor, a ceramic capacitor, an oil-filled breaker and so on) , the same function and effect as the embodiment 1-3 can be obtained.

As described above, according to the embodiments of the present invention, in the power electric apparatus such as the power capacitor and the power switch, which is applied to, for example, the high-frequency apparatuses and large power apparatuses etc., it is apparent that the heat radiation efficiency against the electrical heat generation during the operation of the power electric apparatus can be enhanced and the insulation withstanding voltage characteristic against the shunt current can be improved.

Although the invention has been described above by reference to certain embodiments of the invention, the invention is not limited to the embodiments described above. Modifications and variations of the embodiments described above will occur to those skilled in the art in light of the above teachings . The scope of the invention is defined with reference to the following claims.

1.-7. (canceled)

8. A power electric apparatus of a power capacitor for forming capacitance, comprising:
a casing having a tubular insulation member; and
conductive members closing both ends of the tubular insulation member, the capacitance being formed between the both conductive members in the casing, and
a longitudinal section of a side wall of the insulation member being formed into an arch shape.

9. The power electric apparatus as claimed in claim 8, further comprising:
a fixed electrode installed at one of the conductive members in the casing; and
a movable electrode installed at the other of the conductive members in the casing, and
the capacitance being formed between the fixed electrode and the movable electrode, and wherein
the casing is a vacuum casing, and
by moving the movable electrode and changing a position of the movable electrode with respect to the fixed electrode, the capacitance can be changed.

10. The power electric apparatus as claimed in claim 8, wherein:
an inside diameter and an outside diameter of the side wall of the tubular insulation member are set so that as a position of each diameter becomes closer to a middle from the both end sides in an axial direction of the insulation member, the diameter becomes greater, and also each shape of longitudinal section of an inner peripheral surface and an outer peripheral surface of the side wall is the arch shape.

11. The power electric apparatus as claimed in claim 8, wherein:
an inside diameter and an outside diameter of the side wall of the tubular insulation member are set so that as a position of each diameter becomes closer to a middle from the both end sides in an axial direction of the insulation member, the diameter becomes smaller, and also each shape of longitudinal section of an inner peripheral surface and an outer peripheral surface of the side wall is the arch shape.

12. The power electric apparatus as claimed in claim 8, wherein:
the insulation member is made of ceramic material.

13. A power electric apparatus of a switch for performing shut-off/power-on (open/close), comprising:
a casing having a tubular insulation member; and
conductive members closing both ends of the tubular insulation member and allowing open/close between the both conductive members electrically by changing an electrical distance between the both conductive members, and
a longitudinal section of a side wall of the insulation member being formed into an arch shape.

14. The power electric apparatus as claimed in claim 13, further comprising:
a fixed electrode installed at one of the conductive members in the casing; and
a movable electrode installed at the other of the conductive members in the casing, and wherein
the casing is a vacuum casing, and
by moving the movable electrode for connecting with or disconnecting from the fixed electrode, the open/close between the movable electrode and the fixed electrode can be electrically performed.

15. The power electric apparatus as claimed in claim 13, wherein:
an inside diameter and an outside diameter of the side wall of the tubular insulation member are set so that as a position of each diameter becomes closer to a middle from the both end sides in an axial direction of the insulation member, the diameter becomes greater, and also each shape of longitudinal section of an inner peripheral surface and an outer peripheral surface of the side wall is the arch shape.

16. The power electric apparatus as claimed in claim 13, wherein:
an inside diameter and an outside diameter of the side wall of the tubular insulation member are set so that as a position of each diameter becomes closer to a middle from the both end sides in an axial direction of the insulation member, the diameter becomes smaller, and also each shape of longitudinal section of an inner peripheral surface and an outer peripheral surface of the side wall is the arch shape.

17. The power electric apparatus as claimed in claim 13, wherein:
the insulation member is made of ceramic material.
